(19) United States
(12) Patent Application Publication
(10) Pub. No.: US 2005/0198817 A1
(43) Pub. Date: Sep. 15, 2005

(54) Electrical connector separation devices

(76) Inventor: Kenneth B. Cooper, El Paso, TX (US)

Correspondence Address: MICHAEL A. O'NEIL, P.C., 5949 SHERRY LANE, SUITE 820, DALLAS, TX, 75225, US

(21) Appl. No.: 10/913,031

(22) Filed: Aug. 6, 2004

Related U.S. Application Data
(60) Provisional application No. 60/552,358, filed on Mar. 11, 2004.

(51) Int. Cl. B23P 19/00; H05K 1/00

(52) U.S. Cl. 29/764; 29/762; 29/426.5

(57) ABSTRACT

A separation device for electrical connectors comprises a first tool having an aperture defined by interior walls which are matched in size and shape to the exterior walls of a first component of an electrical connector. The thickness of the tool is matched to the distance between protrusions of the first component. Thus, by engaging the tool with the first component, disengagement between the component parts of the electrical connector is achieved. The separation device further comprises a second tool having an aperture defined by side walls which are matched to the configuration of the exterior walls of the second component of the electrical connector. The first and second tools may be used in combination, or may be combined.

### CLAIM OF PRIORITY

This application claims priority of provisional Application Ser. No. 60/552,358 filed Mar. 11, 2004, currently pending.

### TECHNICAL FIELD

This invention relates generally to the separation of previously engaged electrical connectors, and more particularly to tools which facilitate the separation of electrical connectors.

### BACKGROUND AND SUMMARY OF THE INVENTION

Electrical connectors are widely used in the fabrication of computers and other electronic devices. In order to prevent separation resulting from vibration and similar effects, the component parts of electrical connectors are intentionally designed to be very snug-fitting. Unfortunately, over time the snug-fitting design of electrical connectors renders them almost impossible to separate by the most obvious method of simply grasping the component parts of a connector and applying oppositely directed forces thereto.

The present invention relates to devices for separating electrical connectors which overcome the foregoing and other difficulties which have long since characterized the prior art. In accordance with the broader aspects of the invention, a separation device for electrical connectors comprises at least one tool having at least one aperture comprising interior walls which are closely matched in size and shape to the exterior walls of one component of an electrical connector. The thickness of the tool is matched to the distance between protruding components of the component of the electrical component. Thus, by engaging the tool with the component of the electrical connector and thereafter utilizing the tool to manipulate the component, disengagement between the component parts of the electrical connector can be achieved. The present invention further comprises a second tool having an aperture defined by side walls which are closely matched to the configuration of the exterior walls of the opposite component of the electrical connector. Like the first component, the function of the second tool is to engage its corresponding component of the electrical connector to facilitate manipulation thereof thereby affecting disengagement of component parts of the electrical connector.

The first and second tools of the electrical connector separation device of the present invention may be utilized in combination. In such instances, the first component of the tools of the present invention is engaged with the first component of the electrical connector while the second component of the tool of the present invention is simultaneously engaged with the second component of the electrical connector. The first and second components of the tools of the present invention are then utilized to pry the component parts of the electrical connection apart.

The first and second tools of the electrical connector separation device of the present invention may be combined into a single tool. In such instances the tool is provided with at least one aperture having interior surfaces which match the exterior configuration of both components of an electrical connector. In this manner, manipulation of the component parts of the electrical connector to affect disengagement thereof is facilitated. In those instances in which the two tools of the present invention are combined into a single tool mirror image configurations of the electrical component receiving aperture are preferably provided at opposite ends of the tool.

### BRIEF DESCRIPTION OF THE DRAWINGS

A more complete understanding of the present invention may be had by reference to the following Detailed Description when taken in connection with the accompanying Drawings, wherein:

FIG. 1 is a perspective view illustrating a prior art electrical connector;

FIG. 2 is a perspective view illustrating first and second electrical connector separation tools incorporating the present invention;

FIG. 3A is a side view illustrating the use of the tools of FIG. 2 in the separation of the component parts of an electrical connector;

FIG. 3B is an illustration similar to FIG. 3A further illustrating the utilization of the tools of FIG. 2 in the separation of the component parts of an electrical connector;

FIG. 3C is an end view in which certain component parts have been broken away further illustrating the use of the tools of FIG. 2 in the separation of an electrical connector;

FIG. 4 is a perspective view illustrating an electrical connector separation device comprising a combination of the tools of FIG. 2;

FIG. 5 is a side view illustrating the use of the device of FIG. 4 to effect separation of the component parts of an electrical connector;

FIG. 6 is a view similar to FIG. 5 further illustrating the use of the tool of FIG. 4 to effect separation of the component parts of an electrical connector; and

FIG. 7 is a perspective view illustrating a variation of one of the tools of FIG. 2.

### DETAILED DESCRIPTION

Referring now to the Drawings, and particularly to FIG. 1 thereof, there is shown an electrical connector 10 of the type commonly utilized in the fabrication of computers and other electronic devices. The connector 10 includes a female component 12 having ribs 13 formed thereon. The female component 12 receives a plurality of electrical leads or wires 14. The ends of the leads or wires 14 are electrically and mechanically connected to a plurality of electrical contacts. The female component 12 of the electrical connector 10 is characterized by a rim 16 and a lower edge 18 having a predetermined distance therebetween. The female component 12 of the electrical connector 10 is further characterized by opposed side walls 20 and opposed end walls 22.

The connector 10 further comprises a male component 24 which is received within and matingly engaged with the female component 12. The male component 24 receives a plurality of electrical leads or wires 26 the ends of which are mechanically and electrically connected to a plurality of contacts. As will be appreciated by those skilled in the art, the contacts of the female component 12 are positioned for engagement with the contacts of the male component 24 so as to form electrical connections therebetween. The male component 24 of the connector 10 is provided with a longitudinally extending semicylindrical rib 28 and a pair of laterally extending projections 30. The male component 24 as further characterized by opposed side walls 32, one extending to an edge 33, and opposed end walls 34. When the components 12 and 24 are assembled as shown in FIG. 1, edges 18 and 33 form a gap 35.

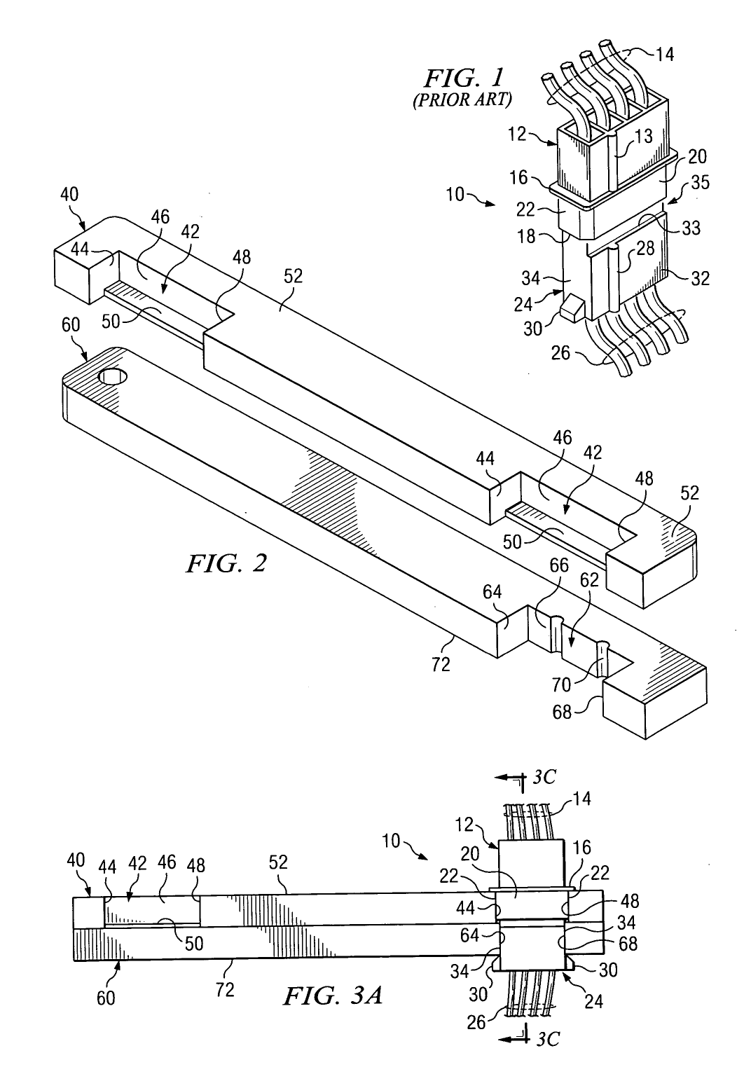

FIG. 2 illustrates a first electrical connector separation tool 40 and a second electrical connection separator tool 60 each comprising the present invention. The electrical connector separation tools 40 and 60 may be used either separately or in combination to affect separation of the component parts of an electrical connector of the type illustrated in FIG. 1 and described hereinabove in connection therewith. Each of the tools 40 and 60 comprises an elongate bar or rod which affords leverage useful in separating the component parts of an electrical connector. The elongate bars or rods comprising the tools 40 and 60 are illustrated in FIG. 2 as being rectangular in cross section, however, the cross-sectional configurations of the tools 40 and 60 is not critical to the practice of the invention and may be varied in accordance with the requirements of particular applications thereof.

The tool 40 comprises apertures located at each end thereof. Each aperture 42 is defined by side walls 44, 46, and 48. The interior surfaces comprising the side walls 44, 46, and 48 are shaped and oriented to matingly engage with one of the side walls 20 and the end walls 22 of the female component 12 of the electrical connector 10. The tool 40 further includes lips or edges 50 positioned to engage the gap 35 extending between the edge 18 of the female component 12 of the electrical connector 10 and the edge 33 of the male component 24. The tool 40 further comprises upper surfaces 52 which surround the apertures 42 and which are positioned to engage the under surface of the rim 16 of the female component 12 of the electrical connector 10 when the lip or edge 50 is engage with the edge 18 thereof.

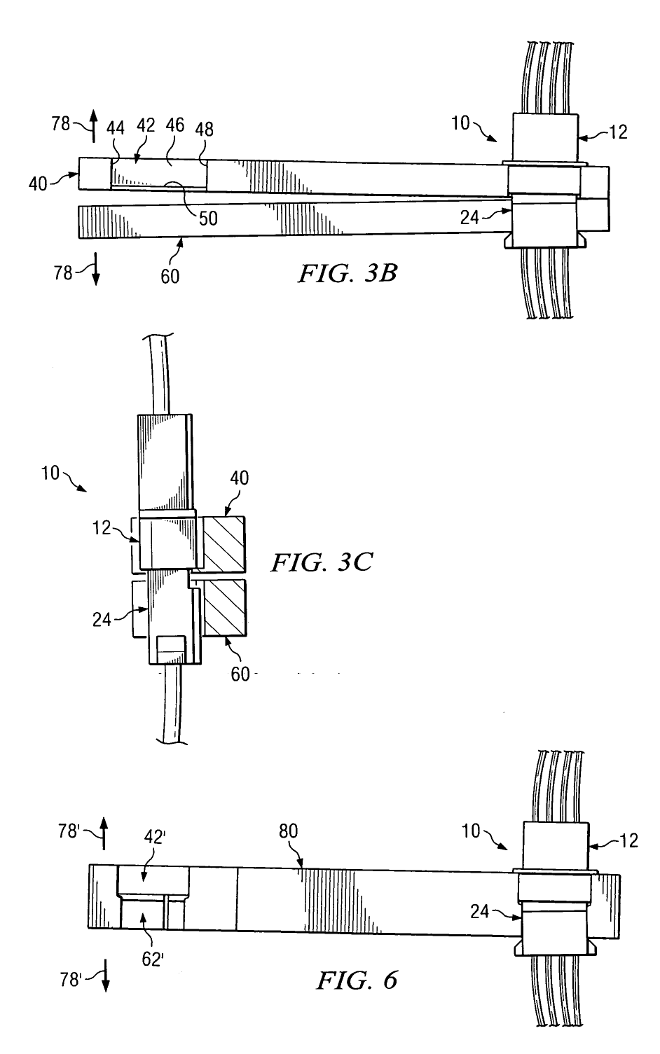

FIG. 3A illustrates the tool 40 engaged with the female component 20 of the electrical connector 10. As is clearly shown in FIG. 3A, an upper surface 52 of the tool 40 is positioned in engagement with the underside of the rim 16 of the female component 12 of the electrical connector 10. Surfaces 44 and 48 of the tool 40 grippingly engage the end walls 22 of the component 12. Although not shown in FIG. 3A, the surface 46 of one of the apertures 42 of the tool 40 engages one of the side walls 20 of the female component 12 of the electrical connector 10 and the corresponding lip or edge 50 engages the gap 35 defined by the edges 18 and 33.

It will therefore be understood that the tool 40 provides a secure connection to the female component 12 of the electrical connector 10. Assuming that the tool 60 is not used, the male component 24 of the electrical connector 10 can be engaged by the fingers of a hand of the operator of the tool 40 or by means of a conventional hand tool such as a pair of pliers. With the female component 12 of the electrical connector 10 securely held in place by the tool 40, the male component 24 of the electrical connector 10 can then be pulled free from the female component 12 thereof.

Referring again to FIG. 2, the tool 60 comprises an aperture 62 defined by side walls 64, 66, and 68. The interior surfaces comprising the side walls 64, 66, and 68 are shaped and oriented to matingly engage one of the side walls 32 and the end walls 34 of the male component of the electrical connector 10. The tool 60 further includes a semicylindrical slot 70 which receives the semicylindrical rib 28 of the male component 24 of the electrical connector 10. The tool 60 further comprises a lower surface 72 which engages the projections 30 of the component 24 of the electrical connector 10.

FIG. 3A also illustrates the tool 60 engaged with the male component 24 of the electrical connector 10. As is clearly shown in FIG. 3A, the lower surface 72 of the tool 60 engages the laterally extending projections 30 of the male component 24 of the electrical connector 10. The surfaces 64 and 68 of the tool 60 grippingly engage the end walls 34 of the component 24. Although not shown in FIG. 3A, the surface 66 of the aperture 62 of the tool 60 engages one of the side walls 32 of the male component 24 of the electrical connector 10.

It will therefore be understood that the tool 60 provides a secure connection to the male component 24 of the electrical connector 10. Assuming that the tool 40 is not used, the female component 12 can be engaged by the fingers of a hand of the operator of the tool 60 or the means of a conventional hand tool such as a pair of pliers. With the male component 24 of the electrical connector 10 securely held in place by the tool 60, the female component 12 of the electrical connector 10 can then be pulled free from the male component 24 thereof.

FIGS. 3A, 3B, and 3C illustrate the use of the tools 40 and 60 in combination to separate the components 12 and 24 comprising the electrical connector 10. The tool 40 grippingly engages the female component 12 in the manner described hereinabove. The tool 60 grippingly engages the male component 24 in the manner described hereinabove. When the components 12 and 24 of the electrical connector 10 are grippingly engaged by the tools 40 and 60, the tools are separated as indicated by the arrows 78 in FIG. 3B thereby disengaging the components 12 and 24 of the electrical connector 10 one from another.

FIGS. 3A and 3B illustrate the tools 40 and 60 extending in the same direction relative to the electrical connector 10. However, as will be appreciated by those skilled in the art, because the tool 40 has apertures 42 located at both ends thereof, the tools 40 and 60 can also extend in opposite directions relative to the electrical connector 10 to effect separation between the component parts thereof.

Referring to FIGS. 4, 5, and 6 there is shown an electrical connector separation device 80 comprising a combination of the electrical connector separation tools 40 and 60 illustrated in FIG. 2 and described hereinabove in conjunction therewith. Many of the component parts of the electrical connector separation device 80 are substantially identical to component parts of the tools 40 and 60. Such identical component parts are designated in FIGS. 4, 5, and 6 with the same reference numerals utilized in the foregoing description of the tools 40 and 60, but are differentiated therefrom by means of a prime (′) designation.

Referring particularly to FIG. 4, the tool 80 comprises the tools 40 and 60 of FIG. 2 laid one on top of another and joined into a unitary construction. The tool 80 differs from the tools 40 and 60 in that the tool 80 is provided with mirror images of the apertures 42 and 62 of the tools 40 and 60, respectively, located at opposite ends of the tool 80. In this manner, separation of the components 12 and 24 comprising the electrical connector 10 is facilitated regardless of the orientation of the electrical connector 10.

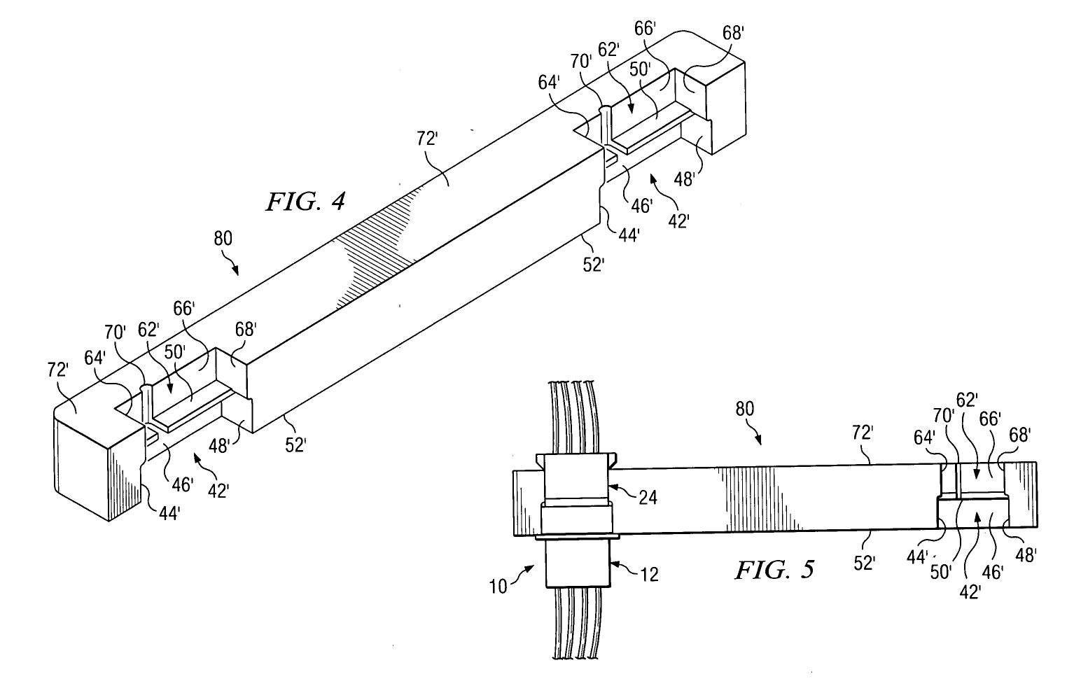

Utilization of the electrical connector separation device 80 to affect separation of the components 12 and 24 of the electrical connector 10 is illustrated in FIGS. 5 and 6. The various surfaces, etc. comprising the apertures 42′ and 62′ situated at a selected end of the device 80 are grippingly engaged with the corresponding surfaces, etc. comprising the components 12 and 24 of the electrical connector 10. The tool 80 is then moved relative to the electrical connector 10 as indicated by the arrows 78′ in FIG. 6 thereby separating the component parts 12 and 24 of the electrical connector 10 one from another.

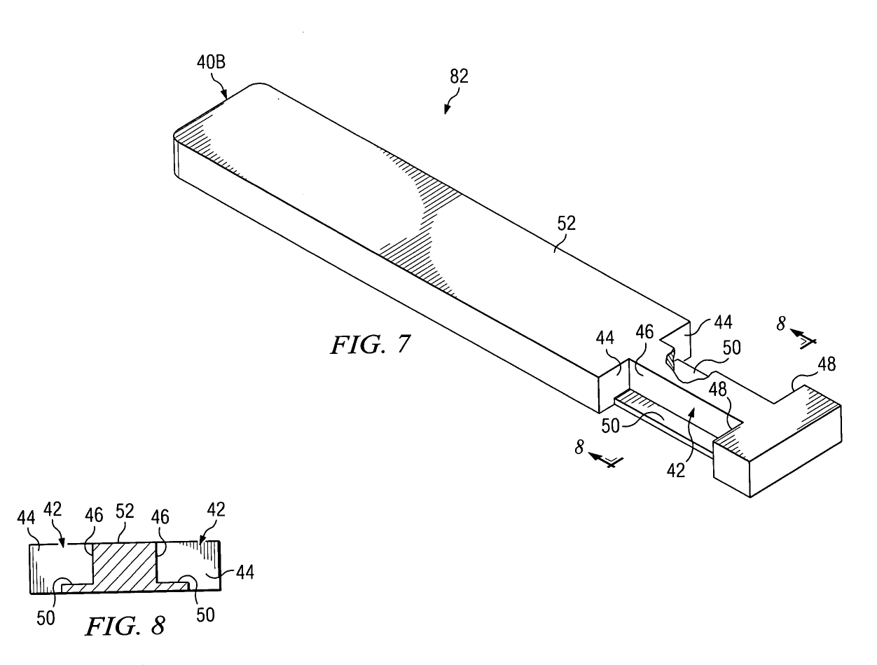

Referring to FIG. 7, there is shown an electrical connector separation device 82 which is similar to the electrical connector separation device 40 shown in FIG. 2 and described hereinabove in conjunction therewith. The electrical connection device 82 differs from the electrical connector separation device 40 in that, as opposed to the electrical connector separation device 40 wherein the two apertures 42 are located at the opposite ends thereof, the apertures 42 are located on opposite sides of the electrical connectors separation device 82. Utilization of the electrical connector separation device 82 to separate the component parts of an electrical connector is substantially identical to the utilization of the electrical connector separation device 40 for the same purpose as illustrated in FIGS. 3A, 3B, and 3C.

Although preferred embodiments of the invention have been illustrated in the accompanying Drawings and described in the foregoing Detailed Description, it will be understood that the invention is not limited to the embodiments disclosed, but is capable of numerous rearrangements, modifications, and substitutions of parts and elements without departing from the spirit of the invention.

1. A tool for separating first and second components of an electrical connector comprising:
an elongate bar having opposed ends and having at least one aperture formed therein adjacent one of the ends;
the aperture being defined by a plurality of side walls each characterized by dimensions which are closely matched to the dimensions of one of the side walls of the first component of the electrical connector;
the elongate bar being further characterized by opposed surfaces which are closely matched to dimensions characterizing protrusions extending from said first component of the electrical connector;
whereby said first component of the electrical connector is grippingly received within the aperture of the elongate bar thereby facilitating manipulation of said first component of the electrical connector with respect to the other component thereof to facilitate disengagement therebetween.

2. A second tool for use in combination with the tools of claim 1 to separate the first and second components of the electrical connector comprising:
an elongate bar having opposed ends and having at least aperture formed therein adjacent one of the ends;
the aperture being defined by a plurality of side walls each characterized by dimensions which are closely matched to the dimensions of one of the side walls of the second component of the electrical connector;
the elongate bar being further characterized by opposed surfaces which are closely matched to dimensions characterizing protrusions extending from said second component of the electrical connector;
whereby said second component of the electrical connector is grippingly received within the aperture of the elongate bar comprising the second tool thereby facilitating manipulation of the second component of the electrical connector with respect to the first component thereof to facilitate this engagement therebetween.

3. The tools for separating first and second components of an electrical connector according to claim 2 wherein the first and second tools are utilized to pry the first and second components of the electrical connector apart.

4. The tools for separating first and second components of an electrical connector according to claim 2 wherein the first and second tools are utilized to twist the first and second components of the electrical connector apart.

5. The tool for separating first and second components of an electrical connector according to claim 1 wherein the elongate bar has two substantially identical apertures formed therein, and wherein the substantially identical apertures are located at opposite ends of the elongate bar.

6. The tool for separating first and second components of an electrical connector according to claim 1 wherein the elongate bar has two substantially identical apertures formed therein and wherein the two apertures are located on opposite sides of the elongate bar.

7. The tool for separating first and second components of an electrical connector according to claim 1 further including a lip positioned in the aperture of the elongate bar for engagement with a gap extending between the first and second components of the electrical connector.

8. The tool for separating first and second components of an electrical connector according to claim 7 wherein the elongate bar has two substantially identical apertures formed therein, and wherein the substantially identical apertures are located at opposite ends of the elongate bar.

9. A second tool for use in combination with the tools of claim 8 to separate the first and second components of the electrical connector comprising:
an elongate bar having opposed ends and having at least aperture formed therein adjacent one of the ends;
the aperture being defined by a plurality of side walls each characterized by dimensions which are closely matched to the dimensions of one of the side walls of the second component of the electrical connector;
the elongate bar being further characterized by opposed services which are closely matched to dimensions characterizing protrusions extending from said second component of the electrical connector;
whereby said second component of the electrical connector is grippingly received within the aperture of the elongate bar comprising the second tool thereby facilitating manipulation of the second component of the electrical connector with respect to the first component thereof to facilitate this engagement therebetween.

10. The tool for separating first and second components of an electrical connector according to claim 7 wherein the elongate bar has two substantially identical apertures formed therein and wherein the two apertures are located on opposite sides of the elongate bar.

11. A second tool for use in combination with the tools of claim 10 to separate the first and second components of the electrical connector comprising:
an elongate bar having opposed ends and having at least aperture formed therein adjacent one of the ends;
the aperture being defined by a plurality of side walls each characterized by dimensions which are closely matched to the dimensions of one of the side walls of the second component of the electrical connector;
the elongate bar being further characterized by opposed services which are closely matched to dimensions characterizing protrusions extending from said second component of the electrical connector;
whereby said second component of the electrical connector is grippingly received within the aperture of the elongate bar comprising the second tool thereby facilitating manipulation of the second component of the electrical connector with respect to the first component thereof to facilitate this engagement therebetween.

12. A tool for separating first and second components of an electrical connector comprising:
an elongate bar having opposed ends and having an aperture formed therein adjacent one of the ends;
the aperture being defined by a first plurality of side walls each characterized by dimensions which are closely matched to the dimensions of one of the side walls of the first component of the electrical connector;
the aperture being further defined by a second plurality of side walls each characterized by dimensions which are closely matched to the dimensions of one of the side walls of the second component of the electrical connector;
the elongate bar being further characterized by opposed surfaces which are closely matched to dimensions characterizing protrusions extending from said first and second components of the electrical connector;
whereby said first and second components of the electrical connector are grippingly received within the aperture of the elongate bar thereby facilitating manipulation of the first and second components of the electrical connector with respect to one another to facilitate disengagement therebetween.

13. The tool for separating first and second components of an electrical connector according to claim 12 further characterized by a second aperture formed in the elongate bar at the opposite end thereof from the first aperture and comprising a mirror image of the first aperture.

14. The tool for separating first and second components of an electrical connector according to claim 13 wherein the elongate bar has two substantially identical apertures formed therein, and wherein the substantially identical apertures are located at opposite ends of the elongate bar.

15. The tool for separating first and second components of an electrical connector according to claim 13 wherein the elongate bar has two substantially identical apertures formed therein and wherein the two apertures are located on opposite sides of the elongate bar.

16. The tool for separating first and second components of an electrical connector according to claim 13 further including a lip positioned in the aperture of the elongate bar for engagement with a gap extending between the first and second components of the electrical connector.
